(19) United States
(12) Patent Application Publication
(10) Pub. No.: US 2024/0247391 A1
(43) Pub. Date: Jul. 25, 2024

(54) METHOD FOR PRODUCING METALLIC ALUMINUM AND POLYSILICON WITH HIGH-SILICON ALUMINUM-CONTAINING RESOURCE

(71) Applicant: ZHENGZHOU UNIVERSITY, Zhengzhou (CN)

(72) Inventor: Zhongwei ZHAO, Zhengzhou (CN)

(73) Assignee: ZHENGZHOU UNIVERSITY, Zhenzhou (CN)

(21) Appl. No.: 18/289,876

(22) PCT Filed: Apr. 21, 2022
(86) PCT No.: PCT/CN2022/088123

§ 371 Date: Nov. 7, 2023

(30) Foreign Application Priority Data
May 8, 2021 (CN) 202110514374.5

(51) Int. Cl. C25C 3/36; C25B 1/33; C25B 9/09; C25C 3/08; C25C 3/18; C25C 7/02; C25C 7/04

(52) U.S. Cl. CPC C25C 3/36; C25B 1/33; C25B 9/09; C25C 3/08; C25C 3/18; C25C 7/025; C25C 7/04

(57) ABSTRACT

The present application belongs to the technical field of aluminum metallurgy, and specifically relates to a method for producing metallic aluminum and polysilicon with a high-silicon aluminum-containing resource. The method includes: pretreating the high-silicon aluminum-containing resource to obtain an aluminum-silicon oxide material; the aluminum-silicon oxide material is used to produce a metallic aluminum product and a copper-aluminum-silicon alloy with silicon enriched by molten salt electrolysis in a double-chamber electrolytic cell; and the copper-aluminum-silicon alloy is used to produce an aluminum-silicon alloy and/or polysilicon by molten salt electrolysis in a single-chamber electrolytic cell, and further separating the aluminum-silicon alloy by physical methods to obtain polysilicon. The present application has characteristics such as low production cost, continuous electrolysis operations, high product quality, and environmental friendliness.

### TECHNICAL FIELD

The present application belongs to the technical field of aluminum metallurgy, and particularly relates to a method for producing metallic aluminum and polysilicon with a high-silicon aluminum-containing resource.

### BACKGROUND

As an important light metal, aluminum is widely used in fields such as transportation, instruments, packaging, building materials, and electric wires. In 2020, a production of primary aluminum (electrolytic aluminum) in China was 37.08 million tons, which ranked first among all non-ferrous metals.

In the prior art, metallic aluminum is produced by the traditional Hall-Heroult molten salt electrolysis process, where the pre-baked anode electrolytic cell as the electrolysis device mainly includes carbon anodes, cryolite molten salt electrolyte, and carbon cathode; metallurgical grade alumina is adopted as a raw material; and electrolysis is conducted at 900° C. to 960° C. to obtain primary aluminum, during which the carbon anode is continuously consumed to produce a CO₂-based gas. Although this method has been widely used, there are many problems: (1) The electrolysis requires a large energy consumption. An electricity consumption per ton of aluminum is about 13,000 kW·h, and an electric energy efficiency is only about 50%. (2) A consumption of the carbon anode is large. Replacing anodes operation affects production efficiency, and a mixed gas including CO₂, CO, SO₂, and fluorocarbons produced accordingly pollutes the environment. (3) The impurity removal or refining is not allowed. During electrolysis, some oxides (such as Fe₂O₃, SiO₂, or TiO₂) that is more electropositive than aluminum in the raw material will be reduced at the cathode together with Al, making a primary aluminum product have a low quality and a low grade. In order to ensure a quality of a primary aluminum product, the industry standard YS/T 803-2012 stipulates that a chemical composition of the metallurgical grade alumina is as follows: Al₂O₃≥98.4 wt %, SiO₂≤0.06 wt %, and Fe₂O₃≤0.03 wt %; and the metallurgical grade alumina has specified physical properties such as specific surface area (SSA) and particle size distribution.

In the current alumina industry, in order to meet the product requirements of metallurgical grade alumina and maximize the production profits, bauxite with a hydrated alumina (Al₂O₃·nH₂O, where n=1 or 3) as a main mineral component is often adopted as a production raw material, an alkaline process such as the Bayer process, the sintering process, or the combined process is used to decompose the bauxite, and deep desiliconization is further required for a crude sodium aluminate leaching solution to prevent the SiO₂ impurity content in alumina product from exceeding a limit.

In addition, a large amount of coal gangue and fly ash solid waste is produced in the coal mining and coal-fired power generation industries of China, where in 2019 alone, a fly ash production is as high as 748 million tons and an amount of accumulated coal gangue reaches 8 billion tons or more. Al₂O₃ contents in high-aluminum fly ash and high-aluminum coal gangue can be as high as 40% to 55%, and if Al₂O₃ in the high-aluminum fly ash and high-aluminum coal gangue can be extracted, the dual benefits of resource utilization and environmental protection are achievable. However, due to the dual pressures of the low alumina-silica ratio (A/S) in a raw material and a high quality of a product alumina, the current technologies to extract Al₂O₃ from fly ash or coal gangue still face the challenge of high production costs.

During the process of extracting alumina from aluminum-containing resources, associated SiO₂ is mostly stored in a stack yard as solid waste in the form of red mud, which has the problems of environmental pollution and resource waste. In particular, aluminum-containing resources such as high-silicon bauxite, fly ash, and coal gangue have a high SiO₂ content, and the full utilization of Al₂O₃ or SiO₂ in these aluminum-containing resources to prepare metallic aluminum and polysilicon is of multiple levels of significance.

In conclusion, in terms of the alumina industry, high-quality alumina ore resources are increasingly shorted, a pressure of silicon and iron removal is high, and associated SiO₂ cannot be effectively utilized; and in terms of the electrolytic aluminum industry, the current electrolysis methods generally strictly require the complete dissolution of alumina in an electrolyte, and these methods also have disadvantages such as high requirements for a quality of an alumina raw material, difficult guarantee of the purity of metallic aluminum product, limited electrolyte selection, long production flow, complicated electrolysis operations, and poor adaptability.

### SUMMARY

An objective of the present application is to provide a method for producing metallic aluminum and polysilicon with a high-silicon aluminum-containing resource, which breaks the barrier between the alumina industry and the electrolytic aluminum industry. The present application uses the aluminum element and the silicon element in the high-silicon aluminum-containing resources to produce metallic aluminum and polysilicon, respectively.

In a specific embodiment of the present application, a method for producing metallic aluminum and polysilicon with a high-silicon aluminum-containing resource is provided, including the following steps:
step (1): pretreating the high-silicon aluminum-containing resource to obtain an aluminum-silicon oxide material;
step (2): with the aluminum-silicon oxide material as an electrolysis raw material, conducting molten salt electrolysis in a double-chamber electrolytic cell to prepare metallic aluminum and a copper-aluminum-silicon alloy,
(3): taking the copper-aluminum-silicon alloy out, placing the copper-aluminum-silicon alloy in a single-chamber electrolytic cell, and conducting molten salt electrolysis to prepare an aluminum-silicon alloy and/or polysilicon.

In the method for producing metallic aluminum and polysilicon with a high-silicon aluminum-containing resource according to the specific embodiment of the present application, in step (1), a Al₂O₃/SiO₂ mass ratio in the high-silicon aluminum-containing resource is 1:(0.5-7), and the high-silicon aluminum-containing resource includes one or more selected from the group consisting of high-silicon bauxite, fly ash, coal gangue, kaolin, and alunite; and in the aluminum-silicon oxide material, a total content of Al₂O₃ and SiO₂ is higher than or equal to 90.0 wt %, a content of Al₂O₃ is higher than or equal to 40.0 wt %, and a content of SiO₂ is higher than or equal to 0.1 wt %.

In the method for producing metallic aluminum and polysilicon with a high-silicon aluminum-containing resource according to the specific embodiment of the present application, in step (1), the pretreatment is intended to increase a total content of Al₂O₃ and SiO₂ in the high-silicon aluminum-containing resource and reduce contents of associated impurities such as Fe, Ti, and Na; and according to properties of treatment reagents, pretreatment processes including alkaline pretreatment processes, acidic pretreatment processes, or combined acidic-alkaline pretreatment processes, and specific processes can hardly be listed one by one and only are simply explained as follows:

The alkaline pretreatment processes include: the high-silicon aluminum-containing resource (especially a natural mineral such as bauxite) is decompose by the limestone sintering method, the soda lime sintering method, the pre-desiliconization soda lime sintering method, the pre-desiliconization caustic soda leaching method, or the like to obtain a alkaline sodium aluminate leaching solution, subsequently, sodium aluminate alkaline leaching solution is then used to obtain aluminum silicon oxide material through processes such as seed decomposition and calcination decomposition. These alkaline pretreatment processes are characterized in that a deep desiliconization treatment with lime is not required for the alkaline leaching solution, which can reduce the use of the lime and the generation of a desiliconization residue while retaining a part of SiO₂ in the aluminum-silicon oxide material.

The acidic pretreatment processes include: the high-silicon aluminum-containing resource is decompose by the atmospheric leaching, pressure leaching, roasting-leaching, or the like with an inorganic strong acid (hydrochloric acid, sulfuric acid, or nitric acid) to obtain an acidic aluminum-containing leaching solution, the acidic aluminum-containing leaching solution is used to precipitate an aluminum salt (aluminum chloride, aluminum sulfate, or aluminum nitrate) by condensation and crystallization, alumina materials is produced through the calcination process, and adding a specified amount of an acidic-leaching residue (mainly SiO₂) to the alumina material to obtain the aluminum-silicon oxide material. The acidic pretreatment processes are characterized in that a deep iron/calcium removal treatment is not required for the acidic leaching solution, which can avoid the use of an ion-exchange resin with low production efficiency.

For the high-silicon aluminum-containing resource with a relatively-high Al₂O₃+SiO₂ content itself, such as fly ash, the pretreatment step can be omitted or impurity removal can be conducted through simple alkaline/acidic washing, then the high-silicon aluminum-containing resource can be sent to the double-chamber electrolytic cell as the aluminum-silicon oxide material.

In the method for producing metallic aluminum and polysilicon with a high-silicon aluminum-containing resource according to the specific embodiment of the present application, in step (2), the double-chamber electrolytic cell is divided into an anode chamber and a cathode chamber to physically separate an anode electrolyte from a cathode electrolyte; the anode chamber is provided with an anode, and the cathode chamber is provided with a cathode; a copper-aluminum alloy is accommodated at a bottom of the double-chamber electrolytic cell, and the copper-aluminum alloy is in contact with each of the anode electrolyte and the cathode electrolyte; and under energized operation conditions, the aluminum-silicon oxide material is fed into the anode chamber, such that the metallic aluminum is produced in the cathode chamber and the copper-aluminum alloy at the bottom of the double-chamber electrolytic cell is transformed into the copper-aluminum-silicon alloy.

The reaction principle in the double-chamber electrolytic cell can be summarized as follows: In the anode chamber, the aluminum-silicon oxide material added to the anode electrolyte undergoes an oxidation reaction on the anode to precipitate a gas, aluminum ions (dissolved and/or non-dissolved) and silicon ions (dissolved and/or non-dissolved) in the anode chamber are reduced into aluminum atoms and silicon atoms at an interface between the anode electrolyte and the copper-aluminum alloy, respectively, and then aluminum atoms and silicon atoms enter the liquid copper-aluminum alloy; and in the cathode chamber, the aluminum atoms of the copper-aluminum alloy discharge at an interface between the cathode electrolyte and the copper-aluminum alloy to produce aluminum ions, and the aluminum ions enter the cathode electrolyte and then are reduced into aluminum atoms to produce the metallic aluminum melt, which floats on the cathode electrolyte. With the continuous progression of electrolysis, silicon is continuously enriched in the copper-aluminum alloy, and thus the copper-aluminum alloy is gradually converted into a copper-aluminum-silicon alloy.

In the method for producing metallic aluminum and polysilicon with a high-silicon aluminum-containing resource according to the specific embodiment of the present application, in step (2), the copper-aluminum alloy has a Al content of 55 at % to 80 at % and does not include Si or includes 10 at % or less of Si (because the copper-aluminum alloy is prepared from crude copper and crude aluminum through melting to for reuse, both the crude copper and the crude aluminum may include a specified amount of silicon that has not been completely removed; however, the copper-aluminum alloy is named in this way to distinguish it from the copper-aluminum-silicon alloy with silicon enriched after electrolysis); and the copper-aluminum alloy remains a liquid during a normal electrolytic work, and a density of the copper-aluminum alloy is greater than a density of the anode electrolyte or the cathode electrolyte.

In the method for producing metallic aluminum and polysilicon with a high-silicon aluminum-containing resource according to the specific embodiment of the present application, in step (2), the anode is a carbon anode or an inert anode; and the cathode is one or a composite of two or more selected from the group consisting of graphite, aluminum, and TiB₂/C.

The inert anode materials includes the ceramic materials (such as SnO₂ and doped SnO₂, NiFe₂O₄, CaTiO₃, CaRuO₃, CaRuₓTi₁₋ₓO₃, or ITO), the metallic materials (such as a Cu—Al alloy, a Ni—Fe alloy, or a Ni—Fe—Cu alloy), and the cermet composite material (such as Cu—NiFe₂O₄, Cu—NiO—NiFe₂O₄, Ni—NiO—NiFe₂O₄, Cu—Ni—NiO—NiFe₂O₄, or Ni—CaRuₓTi₁₋ₓO₃).

In the method for producing metallic aluminum and polysilicon with a high-silicon aluminum-containing resource according to the specific embodiment of the present application, in step (2), when the double-chamber electrolytic cell works normally, an anode current density is 0.1 A/cm² to 1.5 A/cm² and a temperature is 800° C. to 1,000° C.

In the method for producing metallic aluminum and polysilicon with a high-silicon aluminum-containing resource according to the specific embodiment of the present application, in step (2), the anode electrolyte is a fluoride system or a chloride system.

When the anode electrolyte is a fluoride system, the fluoride system includes 60 wt % to 90 wt % of a cryolite, 5 wt % to 30 wt % of AlF₃, 1 wt % to 5 wt % of Al₂O₃, and 15 wt % or less of an additive, where the cryolite is one or more selected from the group consisting of Na₃AlF₆, Li₃AlF₆, and K₃AlF₆ and the additive is one or more selected from the group consisting of LiF, NaF, KF, CaF₂, MgF₂, and BaF₂.

According to common knowledge in the prior art, in the electrolyte, AlF₃ and MeF (Me=Li, Na, or K) in a molar ratio of 1:3 are equivalent to and exchangeable with Me₃AlF₆ (Me=Li, Na, or K). The above components and composition are only a common expression, and there are many other expressions, for example, a mass fraction can be converted into a corresponding molar fraction. When the component Me₃AlF₆ (Me=Li, Na, or K) is replaced by the two components AlF₃ and MeF (Me=Li, Na, or K), the electrolyte is composed of AlF₃, MeF (Me=Li, Na, or K), Al₂O₃, and the additive.

Because including the cryolite (Me₃AlF₆, Me=Li, Na, or K) component, the fluoride system anode electrolyte has a specified solubility for the aluminum-silicon oxide material; and the addition of AlF₃ and other fluoride salts or chlorides can reduce a liquidus temperature of the electrolyte and adjust physical and chemical properties such as electrical conductivity of the electrolyte. When the alumina material is added to the fluoride system, the aluminum-silicon oxide material undergoes a dissolution reaction to produce dissolved aluminum-containing ions and silicon-containing ions (such as AlF₄⁻ and SiF₆²⁻, which are represented by Al³⁺ and Si⁴⁺, respectively) and oxygen-containing ions (such as AlOF₅⁴⁻, which is represented by O²⁻). Under an action of an electric field, the oxygen-containing ions in the anode chamber undergo oxidation reactions on the anode to precipitate O₂ or CO₂+CO gas; and the aluminum-containing ions and silicon-containing ions undergo reduction reactions at the interface between the anode electrolyte and the copper-aluminum alloy to produce aluminum atoms and silicon atoms, and the aluminum atoms and silicon atoms enter the copper-aluminum alloy. Corresponding reaction equations are as follows:

O²⁻+1/xC−2e⁻→1/xCOₓ⬆(x=1 or 2), or carbon anode:

O²⁻−2e⁻→0.5O₂⬆; and inert anode:

Al³⁺+3e⁻→Al(copper-aluminum alloy) interface:

Si⁴⁺+4e⁻→Si(copper-aluminum alloy).

The aluminum-silicon oxide material at the interface between the liquid copper-aluminum alloy and the anode electrolyte can be further dissolved in the anode electrolyte and supplements the aluminum-containing ions and silicon-containing ions continuously consumed at the interface to reduce the concentration polarization and avoid the occurrence of side reactions, or directly undergoes a reduction reaction at the interface to ensure that the aluminum-containing ions and/or silicon-containing ions in the anode chamber are continuously reduced into aluminum atoms and/or silicon atoms and the aluminum atoms and/or silicon atoms enter the liquid copper-aluminum alloy.

When the anode electrolyte is a chloride system, the chloride system is CaCl₂) or includes CaCl₂) and one or more selected from the group consisting of NaCl, KCl, BaCl₂, CaF₂, LiCl, and CaO.

The chloride system anode electrolyte has a very low solubility for the aluminum-silicon oxide material, but exhibits a specified solubility for O²⁻. When the aluminum-silicon oxide material is added to the chloride system anode electrolyte, under the action of an electric field, the solid aluminum-silicon oxide material directly undergoes reduction reactions at the interface between the anode electrolyte and the copper-aluminum alloy, where aluminum ions and silicon ions are reduced into aluminum atoms and silicon atoms, respectively, and the aluminum atoms and silicon atoms enter the liquid copper-aluminum alloy; and dissociated O²⁻ is dissolved in the anode electrolyte, migrates to the anode, and then undergoes oxidation reactions on a surface of the anode. Reaction equations are as follows:

Al₂O₃+6e⁻→2Al(copper-aluminum alloy)+3O²⁻ interface:

SiO₂+4e⁻→Si(copper-aluminum alloy)+2O²⁻; and

O²⁻+1/xC−2e⁻→1/xCOₓ⬆(x=1 or 2) or carbon anode:

O²⁻−2e⁻→0.5O₂⬆. inert anode:

Further, in order to adjust the physical and chemical properties of the chloride system anode electrolyte, fluorides of alkali metals, fluorides of alkali earth metals, fluorides of aluminum, oxides of alkali metals, or oxides of alkali earth metals may also be added to the chloride system. A carbonaceous conductive agent or a metal powder is blended into the aluminum-silicon oxide material and then a resulting mixture is molded and sintered, such as to improve an electrochemical reactivity of the aluminum-silicon oxide material at the interface.

In the method for producing metallic aluminum and polysilicon with a high-silicon aluminum-containing resource according to the specific embodiment of the present application, in step (2), the cathode electrolyte includes 20 wt % to 70 wt % of a weighting agent, 15 wt % to 50 wt % of AlF₃, 13 wt % to 40 wt % of NaF, and 20 wt % or less of an additive, where the weighting agent is BaCl₂ and/or BaF₂ and the additive is one or more selected from the group consisting of LiF, Li₃AlF₆, Na₃AlF₆, CaF₂, MgF₂, NaCl, LiCl, CaCl₂, and MgCl₂; and
preferably, the cathode electrolyte includes 20 wt % to 40 wt % of BaF₂, 15 wt % to 50 wt % of AlF₃, 20 wt % to 40 wt % of NaF, and 10 wt % to 20 wt % of CaF₂ or the cathode electrolyte includes 50 wt % to 65 wt % of BaCl₂, 15 wt % to 30 wt % of AlF₃, 13 wt % to 30 wt % of NaF, and 0 wt % to 5 wt % of NaCl.

In the cathode chamber, aluminum atoms in the copper-aluminum alloy discharge at the interface between the copper-aluminum alloy and the cathode electrolyte, the produced Al³⁺ (Al³⁺ represents aluminum-containing ions such as AlF₄⁻, the same below) enters the cathode electrolyte, and the Al³⁺ in the cathode electrolyte is reduced into aluminum atoms at the interface between the cathode or the metallic aluminum melt and the cathode electrolyte and then enters the liquid metallic aluminum product. Reaction equations are as follows:

Al(copper-aluminum alloy)−3e⁻→Al³⁺; and interface:

Al³⁺+3e⁻→Al(metallic aluminum melt). cathode:

In the liquid copper-aluminum alloy, silicon atoms have a lower molar concentration and electrochemical activity than aluminum atoms, and thus atoms discharging at the interface between the copper-aluminum alloy and the cathode electrolyte are mainly aluminum atoms, rather than silicon atoms and other more inert impurities (such as Fe and Mn). Therefore, a purity of the metallic aluminum melt produced due to reduction in the cathode chamber can reach 99.0 wt % or more.

With the progression of electrolysis, in the anode chamber, the aluminum-silicon oxide material is continuously reduced into aluminum atoms and silicon atoms, and the aluminum atoms and silicon atoms enter the copper-aluminum alloy; and in the cathode chamber, aluminum in the copper-aluminum alloy is continuously oxidized and enters the cathode electrolyte, and silicon is retained and enriched in the copper-aluminum alloy, such that the copper-aluminum alloy is gradually converted into a copper-aluminum-silicon alloy.

If a Si content in the copper-aluminum-silicon alloy is not high (Si<5 at %), the copper-aluminum-silicon alloy can be directly retained in the double-chamber electrolytic cell and continues to work, or metallic aluminum is timely supplemented to adjust a composition and melting point of the copper-aluminum-silicon alloy and then a resulting copper-aluminum-silicon alloy continues to work in the double-chamber electrolytic cell, such that silicon is further enriched in the alloy; and when a Si content in the copper-aluminum-silicon alloy is high (such as Si>5 at %), a part or all of the copper-aluminum-silicon alloy at the bottom of the double-chamber electrolytic cell is withdrawn and placed in the single-chamber electrolytic cell, and molten salt electrolysis is conducted to prepare an aluminum-silicon alloy and/or polysilicon.

In the method for producing metallic aluminum and polysilicon with a high-silicon aluminum-containing resource according to the specific embodiment of the present application, in step (3), in the single-chamber electrolytic cell, a bottom melt is a copper-aluminum-silicon alloy anode, a middle melt is a refining electrolyte, and an upper melt is an aluminum melt cathode; and under energized operation conditions, Al and Si in the copper-aluminum-silicon alloy are successively oxidized, enter the refining electrolyte, and then are reduced at the aluminum melt cathode to obtain the aluminum-silicon alloy and/or the polysilicon.

In the method for producing metallic aluminum and polysilicon with a high-silicon aluminum-containing resource according to the specific embodiment of the present application, in step (3), the aluminum melt cathode is a pure metallic aluminum melt or a silicon-containing metallic aluminum melt. The aluminum melt cathode may be added in advance or may be produced gradually during electrolysis.

In the method for producing metallic aluminum and polysilicon with a high-silicon aluminum-containing resource according to the specific embodiment of the present application, in step (3), the refining electrolyte includes 20 wt % to 40 wt % of BaF₂, 40 wt % to 70 wt % of cryolite, 5 wt % to 25 wt % of AlF₃, 0 wt % to 10 wt % of a fluorine-silicon compound, and 0 wt % to 15 wt % of an additive, where the cryolite is one or more selected from the group consisting of Na₃AlF₆, Li₃AlF₆, and K₃AlF₆, the fluorine-silicon compound is one or more selected from the group consisting of Na₂SiF₆, K₂SiF₆, Li₂SiF₆, and SiF₄, and the additive is one or more selected from the group consisting of LiF, NaF, KF, CaF₂, and MgF₂.

A reaction principle in the single-chamber electrolytic cell can be summarized as follows: When the liquid copper-aluminum-silicon alloy is used as an anode, aluminum atoms and silicon atoms in the liquid copper-aluminum-silicon alloy are oxidized into aluminum ions and silicon ions, respectively, and the aluminum ions and silicon ions enter the refining electrolyte, where aluminum atoms will generally be preferentially oxidized and enter the refining electrolyte due to a strong electrochemical activity, and then silicon atoms will be oxidized. The aluminum ions and silicon ions in the refining electrolyte are reduced into aluminum atoms and silicon atoms at the cathode, respectively. If the aluminum melt cathode is a pure metallic aluminum melt, then aluminum atoms and silicon atoms will be fused into the pure metallic aluminum melt to produce a liquid aluminum-silicon alloy; and if the aluminum melt cathode is a silicon-containing metallic aluminum melt, silicon is continuously enriched in the silicon-containing metallic aluminum melt until it is saturated, and finally polysilicon will be precipitated. Reaction equations are as follows:

Al(copper-aluminum-silicon alloy)−3e⁻→Al³⁺ anode:

Si(copper-aluminum-silicon alloy)−4e⁻→Si⁴⁺; and

Al³⁺+3e⁻→Al(metallic aluminum or aluminum-silicon alloy) cathode:

Si⁴⁺+4e⁻→Si(aluminum-silicon alloy and/or polysilicon).

After full electrolysis, aluminum and most of silicon in the copper-aluminum-silicon alloy can be removed to produce crude copper including a small amount of silicon.

In the method for producing metallic aluminum and polysilicon with a high-silicon aluminum-containing resource according to the specific embodiment of the present application, in step (3), when the single-chamber electrolytic cell works normally, an anode current density is 0.01 A/cm² to 1.0 A/cm² and a temperature is 800° C. to 1,100° C.

In the method for producing metallic aluminum and polysilicon with a high-silicon aluminum-containing resource according to the specific embodiment of the present application, in step (3), the aluminum-silicon alloy is used to produce polysilicon by physical methods and/or chemical methods, where the physical methods include one or more selected from the group consisting of the liquation method, the segregation in solidification process, the vacuum distillation method, and the directional solidification method, and the chemical methods include the acid pickling method and the electrorefining method; and the physical method is preferred.

The aluminum-silicon alloy is separated by the physical method to obtain polysilicon and crude aluminum, where according to a specific composition, the crude aluminum can be processed into an aluminum alloy material, and can also be fused with the above crude copper to obtain a copper-aluminum alloy, which is returned to step (2).

Therefore, there are two ways to produce polysilicon: polysilicon is obtained directly in the single-chamber electrolytic cell; and polysilicon is obtained through physical separation of the aluminum-silicon alloy.

The present application has the following beneficial effects:

(1) During the process of producing an aluminum-silicon oxide material from a high-silicon aluminum-containing resource, only a simple pretreatment is required or the leaching solution does not require a deep silicon/iron removal treatment; and the two elements of aluminum and silicon in the high-silicon aluminum-containing resource are fully utilized, which can not only reduce the generation of waste residue and the pressure of impurity removal procedures, but also lead to metallic aluminum, polysilicon, and aluminum-silicon alloy products, indicating strong economy.

(2) The electrolysis process is continuous and has strong operability. Both the double-chamber electrolytic cell and the single-chamber electrolytic cell allow continuous feeding, continuous discharging, and closed circulation of copper. In addition, in the traditional electrolytic cell, there needs to be a specified solubility and dissolution rate of alumina in an electrolyte, otherwise the non-dissolved alumina material will pass through a cathode aluminum melt to form a crust at a bottom of the electrolytic cell, which affects normal operations of the electrolytic cell. However, a bottom layer of the double-chamber electrolytic cell used in the present application is a liquid copper-aluminum alloy, and a density of the liquid copper-aluminum alloy is greater than a density of an electrolyte or an aluminum-silicon oxide material, such that, even if the excessive aluminum-silicon oxide material added locally will remain at the interface between the copper-aluminum alloy and the electrolyte and continue to participate in dissolution or an electrochemical reaction, which not only improves the operational adaptability of the electrolytic cell, but also improves the direct utilization of the aluminum-silicon oxide material.

(3) The electrolytic cell has a function of purification and impurity removal. Both the double-chamber electrolytic cell and the single-chamber electrolytic cell have a function of impurity removal. In the double-chamber electrolytic cell, a liquid copper-aluminum alloy is in contact with an electrolyte to construct an electrochemical reaction interface, where impurities more active than Al and Si (such as Ca and Na) will be trapped in an anode electrolyte, and impurities more inert than Al and Si (such as Fe and Mn) will be enriched in the copper-aluminum alloy, such that impurities in the raw material and impurities produced by a corroded inert anode all can be effectively controlled, which ensures that a purity of a metallic aluminum melt in a cathode chamber is higher than or equal to 99.0 wt %. In the single-chamber electrolytic cell, inert impurities enriched in the copper-aluminum-silicon alloy are difficult to react, and have a little impact on a purity of an aluminum-silicon alloy (a product at cathode) and/or a purity of polysilicon.

(4) The method of the present application is energy-saving and eco-friendly, and allows clean production. In the alumina industry, the present application can not only utilize the refractory natural high-silicon bauxite and solid waste such as fly ash and coal gangue to produce an aluminum-silicon oxide material, but also avoid the waste generated by a deep impurity removal procedure. In the electrolytic aluminum industry, a low-temperature electrolyte and an inert anode are used in combination in the electrolytic cell of the present application, which can not only improve the electric energy efficiency and current efficiency, but also reduce the generation of greenhouse gases, toxic gases, anode scraps, and waste cathode carbon blocks.

### BRIEF DESCRIPTION OF THE DRAWINGS

To describe the technical solutions in the embodiments of the present application or in the prior art clearly, the accompanying drawings required for describing the embodiments or the prior art are briefly described below. Apparently, the accompanying drawings in the following description merely show some embodiments of the present application, and a person of ordinary skill in the art may still derive other accompanying drawings from these accompanying drawings without creative efforts.

FIG. 1 is a flow chart of the method for producing metallic aluminum and polysilicon with a high-silicon aluminum-containing resource;

FIG. 2 is a schematic diagram of a cross section of the double-chamber electrolytic cell of the present application,
where reference numerals in FIG. 2: 1: insulating separator, 2: cathode, 3: metallic aluminum, 4: cathode electrolyte, 5: copper-aluminum alloy, 6: electrolytic cell body, 7: anode electrolyte, and 8: anode; and

FIG. 3 is a schematic diagram of a cross section of the single-chamber electrolytic cell of the present application,
where reference numerals in FIG. 3: 9: cathode, 10: aluminum melt, 11: refining electrolyte, 12: copper-aluminum-silicon alloy, 13: conductive carbon block, 14: conductive steel bar, 15: electrolytic cell body, and 16: insulating refractory brick liner.

### DETAILED DESCRIPTION OF THE EMBODIMENTS

To make the objectives, technical solutions, and advantages of the present application clearly, the technical solutions of the present application will be described in detail below. Apparently, the embodiments described are merely some rather than all of the embodiments of the present application. All other embodiments obtained by persons of ordinary skill in the art based on the embodiments of the present application without creative efforts should fall within the protection scope of the present application.

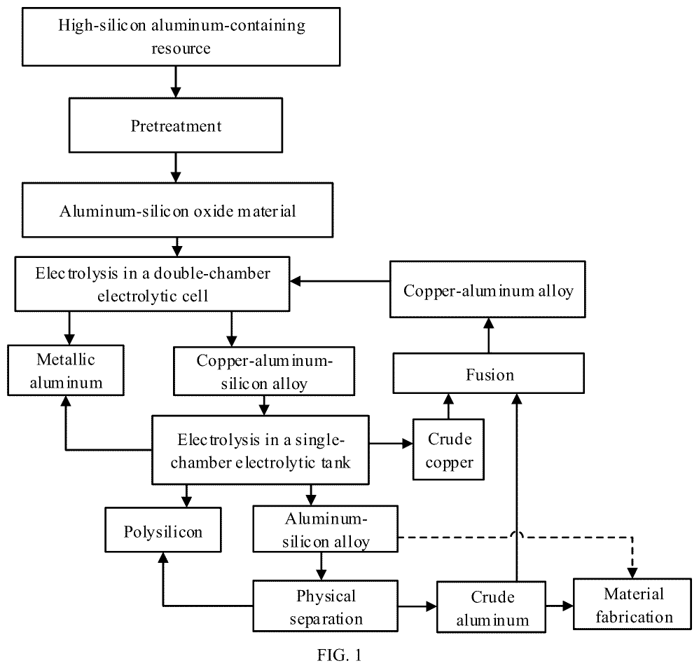

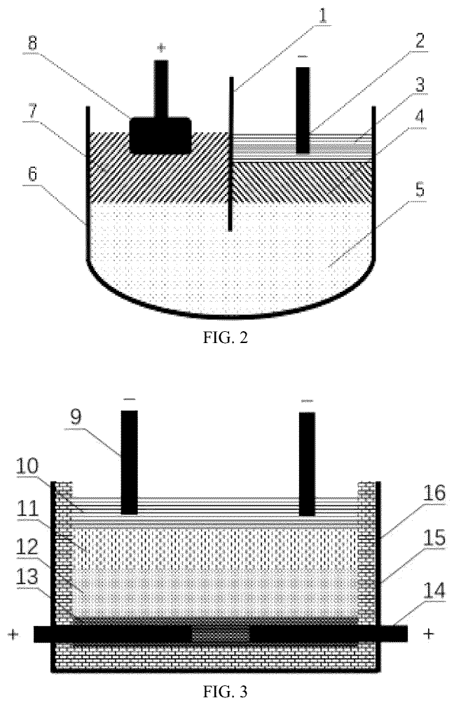

As shown in FIG. 1, a method for producing metallic aluminum and polysilicon with a high-silicon aluminum-containing resource is provided, mainly including the following steps:

step (1): the high-silicon aluminum-containing resource is pretreated to obtain an aluminum-silicon oxide material;

step (2): with the aluminum-silicon oxide material as an electrolysis raw material, molten salt electrolysis is conducted in a double-chamber electrolytic cell to prepare metallic aluminum and a copper-aluminum-silicon alloy; and

step (3): the copper-aluminum-silicon alloy is taken out and placed in a single-chamber electrolytic cell, and molten salt electrolysis is conducted to prepare an aluminum-silicon alloy and/or polysilicon.

In step (1), a Al₂O₃/SiO₂ mass ratio in the high-silicon aluminum-containing resource is 1:0.5 to 1:7, and the high-silicon aluminum-containing resource includes one or more selected from the group consisting of high-silicon bauxite, fly ash, coal gangue, kaolin, and alunite; and in the aluminum-silicon oxide material, a total content of Al₂O₃ and SiO₂ is higher than or equal to 90.0 wt %, a content of Al₂O₃ is higher than or equal to 40.0 wt %, and a content of SiO₂ is higher than or equal to 0.1 wt %. A pretreatment process includes an alkali process, an acid process, and a combined process, and is characterized in that no deep desiliconization procedure or no deep iron/calcium removal procedure is required.

In step (2), the double-chamber electrolytic cell is shown in FIG. 2, where an electrolytic cell body 6 is divided by an insulating separator 1 into an anode chamber and a cathode chamber to physically separate an anode electrolyte 7 from a cathode electrolyte 4; the anode chamber is provided with an anode 8 (carbon anode or inert anode), and the cathode chamber is provided with a cathode 2 (ordinary graphite cathode or wettable cathode); and a copper-aluminum alloy 5 is accommodated at a bottom of the double-chamber electrolytic cell, and the copper-aluminum alloy 5 is in contact with each of the anode electrolyte 7 and the cathode electrolyte 4.

When the double-chamber electrolytic cell is energized and operates at 800° C. to 1,000° C., an anode current density is controlled at 0.1 A/cm² to 1.5 A/cm², and an aluminum-silicon oxide material is fed into the anode chamber, the aluminum-silicon oxide material undergoes an oxidation reaction on the anode to precipitate a gas, aluminum ions (dissolved and/or non-dissolved) and silicon ions (dissolved and/or non-dissolved) in the anode chamber are reduced into aluminum atoms and silicon atoms at the interface between the anode electrolyte 7 and the copper-aluminum alloy 5, respectively, and then the aluminum atoms and silicon atoms enter the liquid copper-aluminum alloy 5; and in the cathode chamber, the aluminum atoms of the copper-aluminum alloy 5 discharge at the interface between the cathode electrolyte 4 and the copper-aluminum alloy 5 to produce aluminum ions, and the aluminum ions enter the cathode electrolyte 4 and then are reduced into aluminum atoms to produce a liquid metallic aluminum melt 3, which floats on the cathode electrolyte 4. With the continuous progression of electrolysis, silicon is continuously enriched in the copper-aluminum alloy 5, and thus the copper-aluminum alloy is gradually converted into a copper-aluminum-silicon alloy.

If a Si content in the copper-aluminum-silicon alloy 5 is not high (Si<5 at %), the copper-aluminum-silicon alloy can be directly retained in the double-chamber electrolytic cell and continues to work, or metallic aluminum is timely supplemented to adjust a composition and melting point of the copper-aluminum-silicon alloy and then a resulting copper-aluminum-silicon alloy continues to work in the double-chamber electrolytic cell, such that silicon is further enriched in the alloy; and when a Si content in the copper-aluminum-silicon alloy is high (such as Si>5 at %), a part or all of the copper-aluminum-silicon alloy 5 at the bottom of the double-chamber electrolytic cell is withdrawn and placed in the single-chamber electrolytic cell, and molten salt electrolysis is conducted to prepare an aluminum-silicon alloy and/or polysilicon.

In step (3), the single-chamber electrolytic cell is shown in FIG. 3, where a bottom structure of an electrolytic cell body 15 is a conductive carbon block 13 provided with a conductive steel bar 14, and surrounding inner walls of the electrolytic cell body each are provided with an insulating refractory brick liner 16; and in the single-chamber electrolytic cell, a bottom melt is a copper-aluminum-silicon alloy 12 as an anode, a middle melt is a refining electrolyte 11, and an upper melt is an aluminum melt 10 (a pure aluminum melt or an aluminum-silicon alloy melt) communicating with a cathode 9.

When the single-chamber electrolytic cell is energized and operates at a 800° C. to 1,100° C. and an anode current density is controlled at 0.01 A/cm² to 1.0 A/cm², Al and Si in the copper-aluminum-silicon alloy 12 are oxidized successively, enter the refining electrolyte 11, and are reduced at the cathode aluminum melt 10 to produce an aluminum-silicon alloy and/or polysilicon.

The aluminum-silicon alloy is used to produce polysilicon by physical methods and/or chemical methods, where the physical methods include one or more selected from the group consisting of the liquation method, the segregation in solidification process, the vacuum distillation method, and the directional solidification method, and the chemical methods include the acid pickling method and the electrorefining method; and the physical method is preferred.

After full electrolysis in the single-chamber electrolytic cell, aluminum and most of silicon in the copper-aluminum-silicon alloy can be removed to produce crude copper including a small amount of silicon; silicon-containing or silicon-free crude aluminum (a by-product) is obtained after physical separation of the aluminum-silicon alloy; and the crude aluminum and the crude copper are fused to obtain a copper-aluminum alloy, and the copper-aluminum alloy is returned to step (2), thereby completing the closed circulation of copper.

### Example 1

High-aluminum coal gangue (Al₂O₃ content: 42.7 wt %, and aluminum/silicon ratio: 1.5) was calcined at 950° C. for 1.5 h, then ball-milled, washed with dilute hydrochloric acid, and then pre-desiliconized with a 20% NaOH solution at 100° C. for 1 h to obtain a desiliconization ash, and the desiliconization ash was thoroughly mixed with non-metallurgical grade alumina (Al₂O₃ content: 95.9 wt %, and SiO₂ content: 0.20 wt %) to obtain an aluminum-silicon oxide material with a Al₂O₃ content of 86.5 wt % and a SiO₂ content of 7.8 wt %.

A pre-alloyed Cu—Al alloy with an Al content of 55 at % was accommodated at a bottom of a double-chamber electrolytic cell, graphite was adopted as an anode, and graphite was adopted as a cathode. A composition of an anode electrolyte was as follows: 81 wt % Na₃AlF₆+8 wt % AlF₃+3 wt % Al₂O₃+6 wt % KF+2 wt % CaF₂+2 wt % LiF; and a composition of a cathode electrolyte was as follows: 23 wt % BaF₂+27 wt % AlF₃+37 wt % NaF+13 wt % CaF₂. The double-chamber electrolytic cell was heated to 1,000° C. and kept at this temperature for 2 h, a direct current was introduced to control an anode current density at 1.5 A/cm², and after electrolysis started, the aluminum-silicon oxide material was regularly fed, where a total electrolysis time was 60 h. After the electrolysis was completed, an Al content in metallic aluminum (a product at the cathode) was determined to be 99.974 wt %.

After the electrolysis, the copper-aluminum alloy at the bottom of the double-chamber electrolytic cell was converted into a copper-aluminum-silicon alloy with a Si content of 7.6 at %. The copper-aluminum-silicon alloy was taken out and placed as an anode at a bottom of a single-chamber electrolytic cell, a graphite rod was adopted as a cathode, and a refining electrolyte was 30 wt % BaF₂+32 wt % Na₃AlF₆+30 wt % Li₃AlF₆+5 wt % AlF₃+3 wt % Na₂SiF₆. The single-chamber electrolytic cell was heated to 1,000° C. and kept at this temperature for 2 h; first-stage electrolysis was conducted for 3.5 h at 1,000° C. and an anode current density of 0.8 A/cm², and after the first-stage electrolysis was completed, metallic aluminum (a product at the cathode) was taken out; and then the single-chamber electrolytic cell was heated to 1,100° C., second-stage electrolysis was conducted for 3 h at 1,100° C. and an anode current density of 0.2 A/cm² to obtain a liquid aluminum-silicon alloy and a solid polysilicon particle at the cathode.

The aluminum-silicon alloy was first separated by the segregation in solidification process to obtain a polysilicon ingot, and the polysilicon ingot and the solid polysilicon particle were remelted, slowly cooled, and directionally solidified to obtain polysilicon with a purity of 99.9%.

### Example 2

High-silicon bauxite (Al₂O₃ content: 62.8 wt %, and aluminum/silicon ratio: 5.5) was fine-ground and then subjected to autoclaving-leaching with a NaOH solution of Na₂Oₖ=220 g/L at 240° C., a leaching solution was diluted, settled, and filtered to obtain a sodium aluminate solution, and without a deep desiliconization treatment using a lime, the sodium aluminate solution was cooled to 75° C., then subjected to crystal seed decomposition, and then calcined at 1,000° C. to obtain an aluminum-silicon oxide material with a Al₂O₃ content of 97.6 wt % and a SiO₂ content of 0.46 wt %.

A pre-alloyed Cu—Al alloy with an Al content of 75 at % was accommodated at a bottom of a double-chamber electrolytic cell, graphite was adopted as an anode, and graphite was adopted as a cathode. A composition of an anode electrolyte was as follows: 80 wt % K₃AlF₆+12 wt % AlF₃+3 wt % Al₂O₃+3 wt % LiF+2 wt % CaF₂; and a composition of a cathode electrolyte was as follows: 60 wt % BaCl₂+22 wt % AlF₃+17 wt % NaF+1 wt % NaF. The double-chamber electrolytic cell was heated to 900° C. and kept at this temperature for 2 h, a direct current was introduced to control an anode current density at 1.2 A/cm², and after electrolysis started, the aluminum-silicon oxide material was regularly fed, where a total electrolysis time was 12 h. After the electrolysis was completed, an Al content in metallic aluminum (a product at the cathode) was determined to be 99.988 wt %.

The copper-aluminum alloy at the bottom of the double-chamber electrolytic cell was converted into a copper-aluminum-silicon alloy with a Si content of less than 0.1 at %. Thus, the above electrolysis experiment could still be continuously conducted for a long time to continuously produce metallic aluminum in a cathode chamber and enrich silicon in the alloy. When a silicon content in a copper-aluminum-silicon alloy was not less than 5 at %, electrolysis was conducted with the copper-aluminum-silicon alloy as an anode in a single-chamber electrolytic cell to obtain an aluminum-silicon alloy and/or polysilicon.

### Example 3

Fly ash (Al₂O₃ content: 35.3 wt %, and aluminum/silicon ratio: 0.6) was subjected to leaching at 95° C. for 3 h with hydrochloric acid of a concentration of about 30%, where a liquid-to-solid ratio was 5 mL/g; a resulting leaching system was filtered to obtain a crude aluminum chloride solution, and without iron/calcium removal by an ion exchange method or a precipitation method, the crude aluminum chloride solution was directly subjected to evaporative concentration under a negative pressure to obtain an aluminum chloride crystal; and the aluminum chloride crystal was subjected to two-stage calcination at 500° C. and 1,000° C. to obtain an alumina material, and then the alumina material was mixed with a specified amount of a silicon-containing leaching residue to obtain an aluminum-silicon oxide material with a Al₂O₃ content of 82.7 wt %, a SiO₂ content of 10.3 wt %, and a Fe₂O₃ content of 1.1 wt %.

A pre-alloyed Cu—Al alloy with an Al content of 70 at % was accommodated at a bottom of a double-chamber electrolytic cell, a CaRuO₃ ceramic material was adopted as an inert anode, and TiB₂ coated graphite was adopted as a cathode. An anode electrolyte was CaCl₂—LiCl in a molar ratio of 70:30, and a composition of a cathode electrolyte was as follows: 25 wt % BaF₂+40 wt % AlF₃+25 wt % NaF+10 wt % CaF₂. The double-chamber electrolytic cell was heated to 820° C. and kept at this temperature for 2 h, a direct current was introduced to control an anode current density at 0.2 A/cm², and before and after electrolysis started, the aluminum-silicon oxide material was regularly fed, where a total electrolysis time was 24 h. After the electrolysis was completed, an Al content in metallic aluminum (a product at the cathode) was determined to be 99.976 wt %.

The copper-aluminum alloy at the bottom of the double-chamber electrolytic cell was converted into a copper-aluminum-silicon alloy with a Si content of 0.3 at %. Thus, the above electrolysis experiment could still be continuously conducted for a long time to continuously produce metallic aluminum in a cathode chamber and enrich silicon in the alloy. When a silicon content in a copper-aluminum-silicon alloy was not less than 5 at %, electrolysis was conducted with the copper-aluminum-silicon alloy as an anode in a single-chamber electrolytic cell to obtain an aluminum-silicon alloy and/or polysilicon.

### Example 4

High-aluminum fly ash (Al₂O₃ content: 49.0 wt %, and aluminum/silicon ratio: 1.1) was subjected to impurity removal through acid pickling to obtain an aluminum-silicon oxide material with an Al₂O₃ content of 48.4 wt % and a SiO₂ content of 47.3 wt %.

A pre-alloyed Cu—Al alloy with an Al content of 65 at % was accommodated at a bottom of a double-chamber electrolytic cell, graphite was adopted as an anode, and a TiB₂/C composite material was adopted as a cathode. An anode electrolyte was CaCl₂), and a composition of a cathode electrolyte was as follows: 60 wt % BaCl₂+20 wt % AlF₃+20 wt % NaF. The double-chamber electrolytic cell was heated to 860° C. and kept at this temperature for 2 h, a direct current was introduced to control an anode current density at 1.0 A/cm², and before and after electrolysis started, the aluminum-silicon oxide material was regularly fed, where a total electrolysis time was 24 h. After the electrolysis was completed, an Al content in metallic aluminum (a product at the cathode) was determined to be 99.963 wt %.

After the electrolysis, the copper-aluminum alloy at the bottom of the double-chamber electrolytic cell was converted into a copper-aluminum-silicon alloy with a Si content of 9.2 at %. The copper-aluminum-silicon alloy was taken out and placed as an anode at a bottom of a single-chamber electrolytic cell, a graphite rod was adopted as a cathode, and a refining electrolyte was 25 wt % BaF₂+50 wt % Na₃AlF₆+15 wt % AlF₃+5 wt % K₂SiF₆+3 wt % CaF₂+2 wt % LiF. The single-chamber electrolytic cell was heated to 900° C. and kept at this temperature for 2 h; first-stage electrolysis was conducted for 6 h at 880° C. and an anode current density of 1.0 A/cm², and after the first-stage electrolysis was completed, metallic aluminum (a product at the cathode) was taken out; and then the single-chamber electrolytic cell was heated to 1,050° C., second-stage electrolysis was conducted for 4 h at 1,050° C. and an anode current density of 0.5 A/cm² to obtain an aluminum-silicon alloy at the cathode.

The aluminum-silicon alloy was subjected to vacuum distillation (1,100° C., and gas pressure: lower than 1 Pa) to obtain polysilicon with a purity of 99.9%.

### Example 5

Fly ash (Al₂O₃ content: 49.8 wt %, and aluminum/silicon ratio: 1.2) was fine-ground and then pre-desiliconized with a 20% NaOH solution at 120° C., and a resulting system was filtered to obtain a desiliconization liquid and desiliconization ash; CO₂ was blown into the desiliconization liquid, a resulting system was filtered, and a resulting filter residue was dried to obtain white carbon black; the desiliconization ash was subjected to autoclaving-leaching with a NaOH solution of Na₂Oₖ=230 g/L at 250° C., and a resulting leaching system was diluted and then filtered to obtain a sodium aluminate solution and a leaching residue; the leaching residue was sintered with soda lime to further recover Al₂O₃ in the leaching residue; and the sodium aluminate solution was cooled to 75° C. without a deep desiliconization treatment using a lime, a solid aluminum hydroxide crystal seed was added to allow crystal seed decomposition, resulting solid aluminum hydroxide was mixed with the white carbon black, and a resulting mixture was calcined at 900° C. to obtain an aluminum-silicon oxide material with a Al₂O₃ content of 90.4% and a SiO₂ content of 5.6%.

A pre-alloyed Cu—Al alloy with an Al content of 60 at % was accommodated at a bottom of a double-chamber electrolytic cell, a 5 wt % Ni-10 wt % NiO—NiFe₂O₄ metal/ceramic composite material was adopted as an inert anode, and TiB₂ coated graphite was adopted as a cathode. A composition of an anode electrolyte was as follows: 82 wt % Na₃AlF₆+12 wt % AlF₃+2 wt % Al₂O₃+2 wt % CaF₂+1 wt % MgF₂+1 wt % LiF; and a composition of a cathode electrolyte was as follows: 35 wt % BaF₂+30 wt % AlF₃+30 wt % NaF+5 wt % CaF₂. The double-chamber electrolytic cell was heated to 950° C. and kept at this temperature for 2 h, and then energized to control an anode current density at 0.8 A/cm², and after electrolysis started, the aluminum-silicon oxide material was regularly fed, where a total electrolysis time was 16 h. After the electrolysis was completed, an Al content in metallic aluminum (a product at the cathode) was determined to be 99.983 wt %.

The copper-aluminum alloy at the bottom of the double-chamber electrolytic cell was converted into a copper-aluminum-silicon alloy with a Si content of 0.5 at %. Thus, the above electrolysis experiment could still be continuously conducted for a long time to continuously produce metallic aluminum in a cathode chamber and enrich silicon in the alloy. When a silicon content in a copper-aluminum-silicon alloy was not less than 5 at %, electrolysis was conducted with the copper-aluminum-silicon alloy as an anode in a single-chamber electrolytic cell to obtain an aluminum-silicon alloy and/or polysilicon.

### Example 6

Preparation of an alumina material from high-aluminum fly ash (Al₂O₃ content: 45.2 wt %, and aluminum/silicon ratio: 1.2) by an alkali-leaching pre-siliconization-soda lime sintering method: The high-aluminum fly ash raw material was pre-desiliconized with a NaOH solution at 120° C. for 30 min, and a resulting system was filtered to obtain a desiliconization ash; the desiliconization ash was mixed with limestone, raw coal, Na₂CO₃, or the like to obtain a raw material in which a CaO/(SiO₂+TiO₂) molar ratio was 2.0 and a Na₂O/(Al₂O₃+Fe₂O₃) molar ratio was 1.0, and the raw material was sintered at 1,200° C. for 4 h to obtain a sintered material; the sintered material was crushed and then dissolved in an 80° C. sodium carbonate solution to obtain a material solution with a Al₂O₃ content of 90 g/L to 110 g/L, and the material solution was filtered; and without a deep desiliconization treatment using a lime, CO₂ was directly blown into a resulting filtrate to allow carbonation decomposition, and a resulting product was filtered out and calcined to obtain an aluminum-silicon oxide material with an Al₂O₃ content of 96.4 wt % and a SiO₂ content of 0.42 wt %.

A pre-alloyed Cu—Al alloy with an Al content of 65 at % was accommodated at a bottom of a double-chamber electrolytic cell, a Cu-13 wt % Fe-37 wt % Ni alloy material was adopted as an inert anode, and graphite was adopted as a cathode. A composition of an anode electrolyte was as follows: 42.3 wt % Na₃AlF₆+28.2 wt % K₃AlF₆+22 wt % AlF₃+2.5 wt % Al₂O₃+3 wt % CaF₂+2 wt % LiF; and a composition of a cathode electrolyte was as follows: 22 wt % BaF₂+46 wt % AlF₃+26 wt % NaF+4 wt % CaF₂+2 wt % LiF. The double-chamber electrolytic cell was heated to 880° C. and kept at this temperature for 2 h, a direct current was introduced to control an anode current density at 0.6 A/cm², and after electrolysis started, the aluminum-silicon oxide material was regularly fed, where a total electrolysis time was 10 h. After the electrolysis was completed, an Al content in metallic aluminum (a product at the cathode) was determined to be 99.991 wt %.

The copper-aluminum alloy at the bottom of the double-chamber electrolytic cell was converted into a copper-aluminum-silicon alloy with a Si content of less than 0.1 at %. Thus, the above electrolysis experiment could still be continuously conducted for a long time to continuously produce metallic aluminum in a cathode chamber and enrich silicon in the alloy. When a silicon content in a copper-aluminum-silicon alloy was not less than 5 at %, electrolysis was conducted with the copper-aluminum-silicon alloy as an anode in a single-chamber electrolytic cell to obtain an aluminum-silicon alloy and/or polysilicon.

The above are merely specific implementations of the present application, but are not intended to limit the protection scope of the present application. Any variation or replacement readily conceived by a person skilled in the art within the technical scope disclosed in the present application shall fall within the protection scope of the present application. Therefore, the protection scope of the present application should be subject to the protection scope of the claims.

1. A method for producing metallic aluminum and polysilicon with a high-silicon aluminum-containing resource, comprising the following steps:
step (1): pretreating the high-silicon aluminum-containing resource to obtain an aluminum-silicon oxide material;
step (2): with the aluminum-silicon oxide material as an electrolysis raw material, conducting molten salt electrolysis in a double-chamber electrolytic cell to prepare metallic aluminum and a copper-aluminum-silicon alloy,
wherein the double-chamber electrolytic cell is divided into an anode chamber and a cathode chamber to physically separate an anode electrolyte from a cathode electrolyte; the anode chamber is provided with an anode, and the cathode chamber is provided with a cathode; a copper-aluminum alloy is accommodated at a bottom of the double-chamber electrolytic cell, and the copper-aluminum alloy is in contact with each of the anode electrolyte and the cathode electrolyte; and under energized operation conditions, the aluminum-silicon oxide material is fed into the anode chamber, such that the metallic aluminum is produced in the cathode chamber and the copper-aluminum alloy at the bottom of the double-chamber electrolytic cell is transformed into the copper-aluminum-silicon alloy; and
step (3): taking the copper-aluminum-silicon alloy out, placing the copper-aluminum-silicon alloy in a single-chamber electrolytic cell, and conducting molten salt electrolysis to prepare an aluminum-silicon alloy and/or polysilicon,
wherein in the single-chamber electrolytic cell, a bottom melt is a copper-aluminum-silicon alloy anode, a middle melt is a refining electrolyte, and an upper melt is an aluminum melt cathode; and under energized operation conditions, Al and Si in the copper-aluminum-silicon alloy are oxidized, enter the refining electrolyte, and then are reduced at the aluminum melt cathode to obtain the aluminum-silicon alloy and/or the polysilicon.

2. The method for producing the metallic aluminum and polysilicon with the high-silicon aluminum-containing resource according to claim 1, wherein in step (1), a Al₂O₃/SiO₂ mass ratio in the high-silicon aluminum-containing resource is 1:(0.5-7), and the high-silicon aluminum-containing resource comprises one or more selected from the group consisting of high-silicon bauxite, fly ash, coal gangue, kaolin, and alunite.

3. The method for producing the metallic aluminum and polysilicon with the high-silicon aluminum-containing resource according to claim 1, wherein in step (2), the anode is a carbon anode or an inert anode.

4. The method for producing the metallic aluminum and polysilicon with the high-silicon aluminum-containing resource according to claim 1, wherein in step (2), the anode electrolyte is a fluoride system or a chloride system, and
the fluoride system comprises 60 wt % to 90 wt % of a cryolite, 5 wt % to 25 wt % of AlF₃, 1 wt % to 5 wt % of Al₂O₃, and 0 wt % to 15 wt % of an additive, wherein the cryolite is one or more selected from the group consisting of Na₃AlF₆, Li₃AlF₆, and K₃AlF₆ and the additive is one or more selected from the group consisting of LiF, NaF, KF, CaF₂, MgF₂, and BaF₂.

5. The method for producing the metallic aluminum and polysilicon with the high-silicon aluminum-containing resource according to claim 1, wherein in step (2), the cathode electrolyte comprises 20 wt % to 70 wt % of a weighting agent, 15 wt % to 50 wt % of AlF₃, 13 wt % to 40 wt % of NaF, and 20 wt % or less of an additive, wherein the weighting agent is BaCl₂ and/or BaF₂ and the additive is one or more selected from the group consisting of LiF, Li₃AlF₆, Na₃AlF₆, CaF₂, MgF₂, NaCl, LiCl, CaCl₂, and MgCl₂.

6. The method for producing the metallic aluminum and polysilicon with the high-silicon aluminum-containing resource according to claim 1, wherein in step (2), a Al content in the copper-aluminum alloy is 55 at % to 80 at %.

7. The method for producing the metallic aluminum and polysilicon with the high-silicon aluminum-containing resource according to claim 1, wherein in step (3), the refining electrolyte comprises 20 wt % to 40 wt % of BaF₂, 40 wt % to 70 wt % of cryolite, 5 wt % to 25 wt % of AlF₃, 0 wt % to 10 wt % of a fluorine-silicon compound, and 0 wt % to 15 wt % of an additive, wherein the cryolite is one or more selected from the group consisting of Na₃AlF₆, Li₃AlF₆, and K₃AlF₆, the fluorine-silicon compound is one or more selected from the group consisting of Na₂SiF₆, K₂SiF₆, Li₂SiF₆, and SiF₄, and the additive is one or more selected from the group consisting of LiF, NaF, KF, CaF₂, and MgF₂.

8. The method for producing the metallic aluminum and polysilicon with the high-silicon aluminum-containing resource according to claim 1, wherein in step (3), the aluminum melt cathode is a pure metallic aluminum melt or a silicon-containing metallic aluminum melt.

9. The method for producing the metallic aluminum and polysilicon with the high-silicon aluminum-containing resource according to claim 1, wherein
in step (2), when the double-chamber electrolytic cell works normally, an anode current density is 0.1 A/cm² to 1.5 A/cm² and a temperature is 800° C. to 1,000° C.

10. The method for producing the metallic aluminum and polysilicon with the high-silicon aluminum-containing resource according to claim 1, wherein in step (3), the aluminum-silicon alloy is used to produce polysilicon by a physical method and/or a chemical method, wherein the physical method comprises one or more selected from the group consisting of a liquation method, a segregation in solidification process, a vacuum distillation method, and a directional solidification method, and the chemical method comprises an acid pickling method and an electrorefining method.

11. The method for producing the metallic aluminum and polysilicon with the high-silicon aluminum-containing resource according to claim 1, wherein in step (1), in the aluminum-silicon oxide material, a total content of Al₂O₃ and SiO₂ is higher than or equal to 90.0%, a content of Al₂O₃ is higher than or equal to 40.0%, and a content of SiO₂ is higher than or equal to 0.1%.

12. The method for producing the metallic aluminum and polysilicon with the high-silicon aluminum-containing resource according to claim 1, wherein in step (2), the cathode is one or a composite of two or more selected from the group consisting of graphite, aluminum, and TiB₂/C.

13. The method for producing the metallic aluminum and polysilicon with the high-silicon aluminum-containing resource according to claim 1, wherein in step (2), the anode electrolyte is a chloride system, and the chloride system is CaCl₂ or comprises CaCl₂ and one or more selected from the group consisting of NaCl, KCl, BaCl₂, CaF₂, LiCl, and CaO.

14. The method for producing the metallic aluminum and polysilicon with the high-silicon aluminum-containing resource according to claim 1, wherein in step (2), the cathode electrolyte comprises 20 wt % to 40 wt % of BaF₂, 15 wt % to 50 wt % of AlF₃, 20 wt % to 40 wt % of NaF, and 10 wt % to 20 wt % of CaF₂ or the cathode electrolyte comprises 50 wt % to 65 wt % of BaCl₂, 15 wt % to 30 wt % of AlF₃, 13 wt % to 30 wt % of NaF, and 0 wt % to 5 wt % of NaCl.

15. The method for producing the metallic aluminum and polysilicon with the high-silicon aluminum-containing resource according to claim 1, wherein in step (2), and the copper-aluminum alloy remains a liquid during a normal electrolytic work, and a density of the copper-aluminum alloy is greater than a density of the anode electrolyte and a density of the cathode electrolyte.

16. The method for producing the metallic aluminum and polysilicon with the high-silicon aluminum-containing resource according to claim 1, wherein in step (3), when the single-chamber electrolytic cell works normally, an anode current density is 0.01 A/cm² to 1.0 A/cm² and a temperature is 800° C. to 1,100° C.
